(19) United States
(12) Patent Application Publication
(10) Pub. No.: US 2019/0249303 A1
(43) Pub. Date: Aug. 15, 2019

(54) CHEMICAL PRECURSORS AND METHODS FOR DEPOSITING A SILICON OXIDE FILM ON A SUBSTRATE UTILIZING CHEMICAL PRECURSORS

(71) Applicant: ASM IP Holding B.V., Almere (NL)

(72) Inventors: Aurélie Kuroda, Tokyo (JP); Atsuki Fukazawa, Tokyo (JP)

(21) Appl. No.: 16/252,567

(22) Filed: Jan. 18, 2019

Related U.S. Application Data
(60) Provisional application No. 62/628,595, filed on Feb. 9, 2018.

(51) Int. Cl. C23C 16/455; C23C 16/40

(52) U.S. Cl. CPC C23C 16/45553; C07F 7/10; C23C 16/402; C23C 16/45538

(57) ABSTRACT

A chemical precursor and a method for depositing a silicon oxide film on a surface of a substrate within a reaction space by plasma-enhanced atomic layer deposition are disclosed. The chemical precursors may include a Si—O—Si skeleton or a Si—N—Si skeleton.

### CROSS-REFERENCE TO RELATED APPLICATION

This Application claims priority to U.S. Provisional Patent Application No. 62/628,595, entitled “CHEMICAL PRECURSORS AND METHODS FOR DEPOSITING A SILICON OXIDE FILM ON A SUBSTRATE UTILIZING CHEMICAL PRECURSORS,” filed Feb. 9, 2018, the disclosure of which is hereby incorporated herein by reference.

### FIELD OF INVENTION

The present disclosure relates generally to chemical precursors and particular chemical precursor which may be utilized in plasma-enhanced atomic layer deposition processes. The present disclosure also generally relates to methods for depositing a silicon oxide film on a substrate utilizing chemical precursors and particular methods for depositing a silicon oxide film via plasma-enhanced atomic layer deposition processes.

### BACKGROUND OF THE DISCLOSURE

In the field of semiconductor device fabrication, there is a growing need for methods to deposit high quality silicon oxides, both undoped and doped, at a reasonable growth rate. In addition, the method of deposition should preferably be extremely conformal, such that the silicon oxide film may be uniformly deposited over 3D structures comprising high aspect ratio features.

Cyclical deposition processes, such as, for example, atomic layer deposition (ALD), plasma-enhanced atomic layer deposition (PEALD) and cyclical chemical vapor deposition (CCVD), may sequential introduce one or more precursors (reactants) into a reaction chamber wherein the precursors react on the surface of the substrate one at a time in a sequential, self-limiting, manner. Cyclical deposition processes have been demonstrated which produce silicon oxide films with excellent conformality with atomic level thickness control.

Accordingly, methods for depositing silicon oxide films and chemical precursors suitable for the deposition of silicon oxide films are desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments of the disclosure, a chemical precursor is provided. The chemical precursor may have the general formula (I):

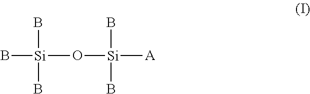

wherein B is selected from a group consisting of H, C_{y}H_{z}, NH₂, NₓC_{y}H_{z}, OH, and OₓC_{y}H_{z}; and wherein A is selected from a group consisting of NH₂, NₓC_{y}H_{z}, and H.

In some embodiments of the disclosure, a chemical precursor is provided. The chemical precursor may have the general formula (II):

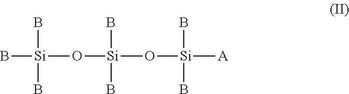

wherein B is selected from a group consisting of H, C_{y}H_{z}, NH₂, NₓC_{y}H_{z}, OH, and OₓC_{y}H_{z}; and wherein A is selected from a group consisting of NH₂, NₓC_{y}H_{z}, and H.

In some embodiments of the disclosure, a chemical precursor is provided. The chemical precursor may have the general formula (III):

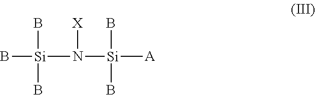

wherein A is selected from a group consisting of NH₂, NₓC_{y}H_{z}, and H; wherein B is selected from a group consisting of H, C_{y}H_{z}, NH₂, NₓC_{y}H_{z}, OH, and OₓC_{y}H_{z}; and wherein X does not comprise C, H, or Si.

In some embodiments of the disclosure, a chemical precursor is provided. The chemical precursor may have the general formula (IV):

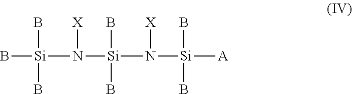

wherein A is selected from a group consisting of NH₂, NₓC_{y}H_{z}, and H; wherein B is selected from a group consisting of H, C_{y}H_{z}, NH₂, NₓC_{y}H_{z}, OH, and OₓC_{y}H_{z}; and wherein X does not comprise C, H, or Si.

In some embodiments of the disclosure, a method of depositing a silicon oxide film on a surface of a substrate within a reaction space by plasma-enhanced atomic layer deposition is provided. The method may comprise: contacting the substrate with a chemical precursor comprising at least one of:

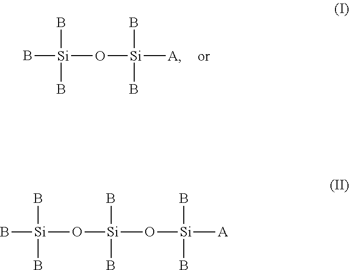

wherein A is selected from a group consisting of NH₂, NₓC_{y}H_{z}, and H; and wherein B is selected from a group consisting of H, C_{y}H_{z}, NH₂, NₓC_{y}H_{z}, OH, and OₓC_{y}H_{z}, contacting the substrate with a reactant comprising at least one of N₂, NₓH_{y}C_{z}, HₓH_{y}, N_{z}H_{y}/Oxidizer, NₓH_{y}/H₂, PₓC_{y}H_{z}, BₓC_{y}H_{z}, O₂, O₃, N₂O, CO₂, H₂O, or H₂/O₂; and applying RF power to the reaction space.

In some embodiments of the disclosure, a method of depositing a silicon oxide film on a surface of a substrate within a reaction space by plasma-enhanced atomic layer deposition is provided. The method may comprise: contacting the substrate with a chemical precursor comprising at least one of:

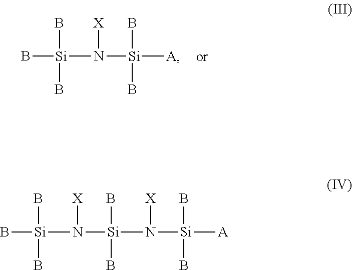

wherein A is selected from a group consisting of NH₂, NₓC_{y}H_{z}, and H; wherein B is selected from a group consisting of H, C_{y}H_{z}, NH₂, NₓC_{y}H_{z}, OH, and OₓC_{y}H_{z}; and wherein X does not comprise C, H, or Si; contacting the substrate with a reactant comprising at least one of O₂, O₃, N₂O, CO₂, H₂0, H₂/O₂, or N_{z}H_{y}/Oxidizer; and applying RF power to the reaction space.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a process flow of an exemplary plasma-enhanced atomic layer deposition process according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “cyclic deposition” may refer to the sequential introduction of precursors (reactants) into a reaction chamber to deposit a film over a substrate and includes deposition techniques such as atomic layer deposition, plasma enhanced atomic layer deposition and cyclical chemical vapor deposition.

As used herein, the term “substrate” may refer to any underlying material or materials that may be used, or upon which, a device, a circuit or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film”, “thin film”, “layer” and “thin layer” may refer to any continuous or non-continuous structures and material deposited by the methods disclosed herein. For example, “film”, “thin film”, “layer” and “thin layer” could include 2D materials, nanorods, nanotubes, or nanoparticles or even partial or full molecular layers or partial or full atomic layers or clusters of atoms and/or molecules. “Film”, “thin film”, “layer” and “thin layer” may comprise material or a layer with pinholes, but still be at least partially continuous.

As used here, the term “precursor” and “chemical precursor” may generally refer to a chemical compound that participates in a chemical reaction that produces another compound, and particular to a compound that constitutes a film matrix, or a main skeleton of a film.

As used herein, the term “reactant” refers to a compound that activates a precursor, modifies a precursor, or catalyzes a reaction of a precursor.

As used herein, the term “skeleton” may refer to a main chain of the chemical precursor, as opposed to the pendant side chains.

As used herein, the term “reaction space” may refer to a reactor or reaction chamber, or an arbitrarily defined volume therein, in which conditions can be adjusted to effect film deposition over a substrate by plasma enhanced atomic layer deposition (PEALD). Typically the reaction space includes surfaces subject to all reaction gas pulses from which gases or particles can flow to the substrate, by entrained flow or diffusion, during normal operation. The reaction space can be, for example, the reaction chamber in a single-substrate PEALD reactor or the reaction chamber of a batch PEALD reactor, where deposition on multiple substrates takes place at the same time.

A number of example materials are given throughout the embodiments of the current disclosure, it should be noted that the chemical formulas given for each of the example materials should not be construed as limiting and that the non-limiting example materials given should not be limited by a given example stoichiometry

The present disclosure includes chemical precursors and deposition methods that may be utilized to deposit a silicon oxide film over a substrate and in particular methods for depositing a silicon oxide film by plasma-enhanced atomic layer deposition (PEALD).

Highly conformal deposition of a silicon oxide film, e.g., greater than 95% step coverage over features with an aspect ratio of greater than 10, has been achieved utilizing atomic layer deposition processes. Such ALD-type process may utilize bis(dimethylamino) dimethylsilane as a chemical precursor and achieve a growth rate per ALD cycle (GPC) of approximately 0.07 nanometers at a substrate deposition temperature of approximately 400° C. However, utilizing such ALD processes and precursors may deposit a silicon oxide film with undesirable materials characteristics, such as, for example, a wet etch rate (WER) ratio compared to a thermal oxide equal to or inferior to 1 may not be obtained utilizing such ALD processes and precursors.

The WER ratio may be decreased by utilizing a precursor comprising Si—O bonds, such as, for example, a tetraethoxysilane precursor. Not to be bound to any particular theory, but the decrease in WER in a silicon oxide film deposited utilizing a precursor comprising Si—O bonds may be due to the strength of the Si—O bonds, originating from the precursor molecule, remaining in the final deposited silicon oxide film. However, the growth rate per cycle for precursors such as tetraethoxysilane comprising Si—O bonds may be undesirably low, e.g., 0.01 nanometers at a substrate temperature of 400° C. The significant decrease in growth rate per cycle observed in the case of tetraethoxysilane, compared to an amino containing precursor, may be due to the poor adsorption of the precursor on a Si—OH surface, which is self-catalyzed by hydrogen bonds in the case of amino containing precursors.

Therefore, the embodiments of the present disclosure may comprise chemical precursors comprising a Si—O—Si skeleton or a Si—N—Si skeleton as well as one or more functional groups which enable efficient adsorption to the substrate upon which silicon oxide deposition is desired as well as a reasonable growth rate per cycle of the silicon oxide film. Accordingly, the embodiments of the disclosure may provide methods to deposit a high quality silicon oxide film utilizing novel plasma-enhanced atomic layer deposition processes which may include continuous reactant and carrier gas flow, thereby reducing processing time, compared with standard PEALD processes, and increased process stability.

In some embodiments of the disclosure, chemical precursors may comprise a Si—O—Si skeleton. In addition, the chemical precursors of the current disclosure may comprise one or more functional groups which favor adsorption on an —OH surface, such as, for example, an amine based functional group. In some embodiments, the chemical precursor may be utilized with a nitrogen based reactant to form a nitrogen doped silicon oxide film. In some embodiments, the chemical precursor may be utilized with an oxygen based reactant to form a pure silicon oxide film. In some embodiments, the chemical precursor may be utilized with a phosphor or boron based precursor to form a doped silicon oxide film.

In some embodiments of the disclosure, the chemical precursor may comprise a Si—O—Si skeleton and may have the general formula I:

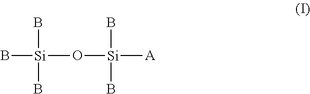

wherein A is selected from a group consisting of NH₂, NₓC_{y}H_{z}, or H; and wherein B is selected from a group consisting of H, C_{y}H_{z}, NH₂, NₓC_{y}H_{z}, OH, and OₓC_{y}H_{z}.

In some embodiments of the disclosure, the chemical precursor may comprise a Si—O—Si skeleton and may have the general formula II:

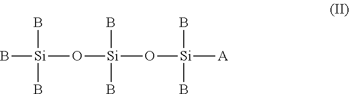

wherein A is selected from a group consisting of NH₂, NₓC_{y}H_{z}, or H; and wherein B is selected from a group consisting of H, C_{y}H_{z}, NH₂, NₓC_{y}H_{z}, OH, and OₓC_{y}H_{z}.

In some embodiments of the disclosure, chemical precursors may comprise a Si—N—Si skeleton. In addition, the chemical precursors of the current disclosure may comprise one or more functional groups which favor adsorption on an —OH surface, such as, for example, an amine based functional group. In some embodiments, the chemical precursor may be utilized with an oxygen based reactant to form a pure silicon oxide film or a nitrogen silicon oxide.

In some embodiments of the disclosure, the chemical precursor may comprise a Si—N—Si skeleton and may have the general formula III:

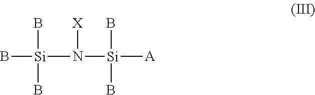

wherein A is selected from a group consisting of NH₂, NₓC_{y}H_{z}, and H; wherein B is selected from a group consisting of H, C_{y}H_{z}, NH₂, NₓC_{y}H_{z}, OH, and OₓC_{y}H_{z}; and wherein X does not comprise C, H, or Si.

In some embodiments of the disclosure, the chemical precursor may comprise a Si—N—Si skeleton and may have the general formula IV:

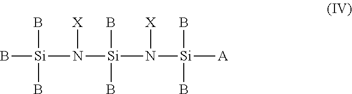

wherein A is selected from a group consisting of NH₂, NₓC_{y}H_{z}, and H; wherein B is selected from a group consisting of H, C_{y}H_{z}, NH₂, NₓC_{y}H_{z}, OH, and OₓC_{y}H_{z}; and wherein X does not comprise C, H, or Si.

In some embodiments of the disclosure, the Si—O—Si skeleton containing chemical precursors and the Si—N—Si skeleton containing chemical precursors, in which the central N is not bound to a H or C atom, are assumed to be retained to some extent in the final deposited silicon oxide film, which may increase the film WER, e.g., in an wet etchant such as hydrofluoric acid (HF).

The embodiments of the disclosure may also include methods for depositing a silicon oxide film on a substrate and particular plasma-enhanced atomic layer deposition (PEALD) processes for depositing a silicon oxide film on a substrate. In some embodiments, the PEALD processes disclosed herein may comprise a continuous flow of the reactant during the deposition cycle, which may enable a reduction in the time period required for reactant flow stabilization, therefore reducing the deposition cycle time. In some embodiments, without any source of energy, e.g., without applying RF power, no reaction occurs between the reactant and the precursor which enables the reactant to constantly flow into the reaction space, and deposition is only achieved when applying the RF power to the reaction space in the PEALD mode.

In some embodiments of the disclosure, the PEALD processes may utilize a constant carrier gas flow. For example, during the precursor feed step, i.e., when the chemical precursor is fed into the reaction space, the carrier gas may be fed into the precursor source vessel. During a purge step, and whilst applying RF power to the reaction space, a bypass valve may be utilized to flow the carrier gas directly into the reaction space, without flowing the carrier gas through the precursor source vessel. Therefore, the precursor and carrier gas mixture may be prevented from flowing into the reaction space during the purge cycle and whilst the RF power is on by closing a valve positioned on the precursor source vessel outlet, before the reaction space. As a result, the variation in total gas flow entering the reaction space between the precursor feed step and the other steps of the PEALD cycle may be reduced, which may also reduce pressure instability in the PEALD process. In addition, in PEALD processes which include long pulse periods, the precursor may be degraded prior to entering the reaction space. However, in PEALD processes utilizing a precursor source vessel bypass valve such degradation of the precursor may be avoided.

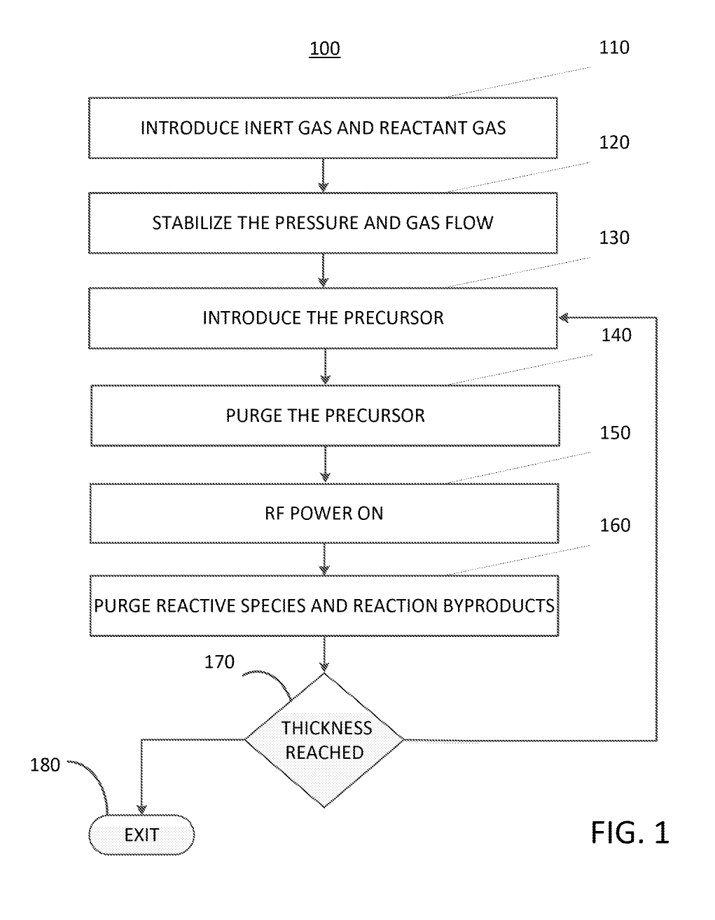

The embodiments of the disclosure may also include methods for depositing a silicon oxide film and particular methods for depositing a silicon oxide film by plasma-enhanced atomic layer deposition (PEALD) processes. In some embodiments of the disclosure a PEALD process may be illustrated with reference to FIG. 1 which comprises exemplary PEALD process 100.

In more detail, the exemplary PEALD process 100 may proceed with a process block 110 comprising, introducing one or more inert gases and a reactant gas into the reaction space. In some embodiments, the inert gas may comprise a carrier gas which may be utilized to convey a precursor to the reaction space. However, during the block 110, the inert carrier gas may flow through a bypass valve configured to allow the inert carrier gas to flow into the reaction space without contacting the precursor held with the precursor source vessel. In some embodiments, the inert carrier gas may comprise at least one of hydrogen, nitrogen, helium, argon, or mixtures thereof. In some embodiment, the flow rate of the inert gas into the reaction space may be greater than 1 slm, or greater than 4 slm, or even greater than 10 slm.

In addition to the inert carrier gas, a reactant gas may be also introduced into the reaction space during process block 110. In some embodiments, the reactant gas for depositing silicon oxide film, or a doped silicon oxide film, may be capable of generating plasma and is not thermally reactive to the precursor without a plasma. In some embodiments of the disclosure, the precursor may comprise a Si—O—Si skeleton and in such embodiments the reactant gas may comprise at least one of N₂, NₓH_{y}C_{z}, HₓH_{y}, N_{z}H_{y}/Oxidizer, NₓH_{y}/H₂, PₓC_{y}H_{z}, BₓC_{y}H_{z}, O₂, O₃, N₂O, CO₂, H₂O, or H₂/O₂. In some embodiments of the disclosure, the precursor may comprise a Si—N—Si skeleton and in such embodiments the reactant gas may comprise at least one of O₂, O₃, N₂O, CO₂, H₂O, H₂/O₂, or N_{z}H_{y}/Oxidizer. In some embodiments, the flow rate of the reactant gas into the reaction space may be greater than 0.1 slm, or greater than 1 slm, or even greater than 5 slm.

The exemplary PEALD process 100 may continue with a process block 120 comprising, stabilizing the pressure within the reaction space and stabilizing the flow of gases into the reaction space. In some embodiments of the disclosure, the pressure within the reaction space may be less than 1300 Pa, or less than 600 Pa, or even less than 300 Pa.

The exemplary PEALD process 100 may proceed with a block 130 comprising, introducing a precursor, e.g., a precursor chemical, into the reaction space and contacting a substrate disposed within the reaction space with the precursor. In some embodiments, of the disclosure the precursor may comprise a Si—O—Si skeleton and may include such chemical precursors as previously disclosed herein. In some embodiments, the precursor may comprise a Si—N—Si skeleton and may include such chemical precursors as previously disclosed herein.

In some embodiments of the disclosure, introducing the precursor, i.e., contacting, the substrate to the precursor may comprise pulsing the precursor over the substrate for a time period of between 0.1 seconds and 2.0 seconds, or from about 0.01 seconds to about 15 seconds, or less than about 60 seconds, less than about 15 seconds or less than about 5 seconds. During the pulsing of the precursor over the substrate the flow rate of the nitrogen precursor may be less than 1000 sccm, or less than 500 sccm, or less than 50 sccm, or even less than 5 sccm.

The exemplary PEALD process 100 may proceed with a process block 140 comprising, purging the precursor from the reaction space. For example, excess precursor gas may be removed from the reaction space, e.g., by pumping with an inert gas. For example, in some embodiments of the disclosure, the methods may comprise a purge cycle wherein the reaction space, and the substrate disposed therein, is purged for time period of less than 1 second, or less than 3 second, or even less than 10 seconds. Excess precursor and any byproducts may be removed with the aid of a vacuum, generated by a pumping system, in fluid communication with the reaction space.

The exemplary PEALD process 100 may proceed with a process block 150 comprising, applying RF power to the reaction space. In some embodiments, the RF power applied to the reaction space is greater than 0.15 W/cm², or greater than 0.7 W/cm², or even greater than 1.5 W/cm². In some embodiments, the duration of a pulse of RF power is less than about 30 seconds, or less than about 10 seconds, or even less than about 3 seconds.

The exemplary PEALD process 100 may proceed with a process block 160 comprising, purging the reactive species and reaction byproducts from the reaction space. For example, excess reactive species may be removed from the reaction space, e.g., by pumping with an inert gas. For example, in some embodiments of the disclosure, the methods may comprise a purge cycle wherein the reaction space, and the substrate disposed therein, is purged for time period of less than 0.1 second, or less than 1 second, or even less than 5 seconds. Excess reactive species and any byproducts may be removed with the aid of a vacuum, generated by a pumping system, in fluid communication with the reaction space.

The exemplary PEALD process 100 may continue with a decision gate 170 which determines if the cyclical PEALD method 100 continues or exits via a process block 180. The decision gate 170 is determined based on the thickness of the silicon oxide film deposited, for example, if the thickness of the silicon oxide film is insufficient for the desired device structure, then the method 100 may return to the process block 130 and the processes of contacting the precursor and applying RF power, whilst continuing supplying reactant gas, may be repeated one or more times. Once the silicon oxide film has been deposited to a desired thickness the method may purge the reaction space of any remaining species and exit via the process block 180 and the silicon oxide film and the underlying semiconductor structure may be subjected to additional processes to form one or device structures.

The PEALD cyclical deposition processes described herein may be performed in a PEALD deposition system with a heated substrate. For example, in some embodiments, methods may comprise heating the substrate to temperature of between approximately 80° C. and approximately 450° C., or even heating the substrate to a temperature of between approximately 250° C. and approximately 400° C. Of course, the appropriate temperature window for any given PEALD process, will depend upon the surface termination and reactant species involved. Here, the temperature varies depending on the precursors and reactants being used and is generally at or below about 700° C. In some embodiments, the deposition temperature is generally at or above about 100° C. for vapor deposition processes, in some embodiments the deposition temperature is between about 100° C. and about 500° C., and in some embodiments the deposition temperature is between about 250° C. and about 450° C. In some embodiments the deposition temperature is less than about 700° C., or less than below about 500° C., or less than about 400° C., or below about 300° C. In some instances the deposition temperature can be below about 200° C., below about 150° C. or below about 100° C. In some instances the deposition temperature can be above about 20° C., above about 50° C. and above about 75° C. In some embodiments of the disclosure, the deposition temperature i.e., the temperature of the substrate during deposition is approximately 400° C.

In some embodiments the growth rate of the silicon oxide film is from about 0.005 Å/cycle to about 5 Å/cycle, from about 0.01 Å/cycle to about 2.0 Å/cycle. In some embodiments the growth rate of the silicon oxide film is more than about 0.05 Å/cycle, more than about 0.1 Å/cycle, more than about 0.15 Å/cycle, more than about 0.20 Å/cycle, more than about 0.25 Å/cycle, or more than about 0.3 Å/cycle. In some embodiments the growth rate of the silicon oxide film is less than about 2.0 Å/cycle, less than about 1.0 Å/cycle, less than about 0.75 Å/cycle, less than about 0.5 Å/cycle, or less than about 0.2 Å/cycle. In some embodiments of the disclosure, the growth rate of the silicon oxide film may be approximately 0.5 Å/cycle.

Films, or layers, comprising silicon oxide deposited according to some of the embodiments described herein may be continuous thin films. In some embodiments the thin films comprising a silicon oxide film deposited according to some of the embodiments described herein may be continuous at a thickness below approximately 100 nanometers, or below approximately 60 nanometers, or below approximately 50 nanometers, or below approximately 40 nanometers, or below approximately 30 nanometers, or below approximately 25 nanometers, or below approximately 20 nanometers, or below approximately 15 nanometers, or below approximately 10 nanometers, or below approximately 5 nanometers, or lower. The continuity referred to herein can be physically continuity or electrical continuity. In some embodiments the thickness at which a film may be physically continuous may not be the same as the thickness at which a film is electrically continuous, and the thickness at which a film may be electrically continuous may not be the same as the thickness at which a film is physically continuous.

In some embodiments, a silicon oxide film deposited according to some of the embodiments described herein may have a thickness from about 20 nanometers to about 100 nanometers. In some embodiments, a silicon oxide film deposited according to some of the embodiments described herein may have a thickness from about 20 nanometers to about 60 nanometers. In some embodiments, a silicon oxide film deposited according to some of the embodiments described herein may have a thickness greater than about 20 nanometers, or greater than about 30 nanometers, or greater than about 40 nanometers, or greater than about 50 nanometers, or greater than about 60 nanometers, or greater than about 100 nanometers, or greater than about 250 nanometers, or greater than about 500 nanometers, or greater. In some embodiments a silicon oxide film deposited according to some of the embodiments described herein may have a thickness of less than about 50 nanometers, less than about 30 nanometers, less than about 20 nanometers, less than about 15 nanometers, less than about 10 nanometers, less than about 5 nanometers, less than about 3 nanometers, less than about 2 nanometers, or even less than about 1 nanometer.

In some embodiments of the disclosure, the silicon oxide film may be deposited on a three-dimensional structure, e.g., a non-planar substrate comprising high aspect ratio features. In some embodiments, the step coverage of the silicon oxide film may be equal to or greater than about 50%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

In some embodiments of the disclosure, the silicon oxide films deposited according to the methods disclosed may have a WER ratio compared to a thermal oxide of greater than 1.5, or greater than 2, or even greater than 2.5.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A chemical precursor having the general formula I: 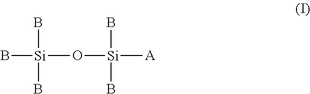
wherein A is selected from a group consisting of NH₂, NₓC_{y}H_{z}, and H; and
wherein B is selected from a group consisting of H, C_{y}H_{z}, NH₂, NₓC_{y}H_{z}, OH, and OₓC_{y}H_{z}.

2. A chemical precursor having the general formula II: 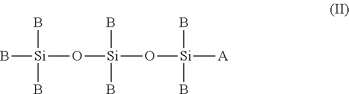
wherein A is selected from a group consisting of NH₂, NₓC_{y}H_{z}, and H; and
wherein B is selected from a group consisting of H, C_{y}H_{z}, NH₂, NₓC_{y}H_{z}, OH, and OₓC_{y}H_{z}.

3. A chemical precursor having the general formula III: 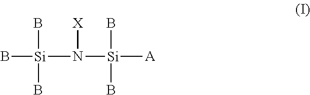
wherein A is selected from a group consisting of NH₂, NₓC_{y}H_{z}, and H;
wherein B is selected from a group consisting of H, C_{y}H_{z}, NH₂, NₓC_{y}H_{z}, OH, and OₓC_{y}H_{z}; and
wherein X does not comprise C, H, or Si.

4. A chemical precursor having the general formula IV: 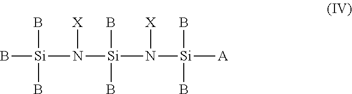
wherein A is selected from a group consisting of NH₂, NₓC_{y}H_{z}, and H;
wherein B is selected from a group consisting of H, C_{y}H_{z}, NH₂, NₓC_{y}H_{z}, OH, and OₓC_{y}H_{z}; and
wherein X does not comprise C, H, or Si.

5. A method of depositing a silicon oxide film on a surface of a substrate within a reaction space by plasma-enhanced atomic layer deposition (PEALD), the method comprising:
contacting the substrate with a chemical precursor comprising at least one of: 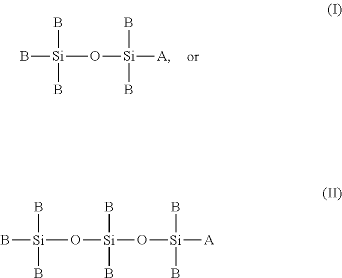
wherein A is selected from a group comprising NH₂, NₓC_{y}H_{z}, or H; and
wherein B is selected from a group comprising H, C_{y}H_{z}, NH₂, NₓC_{y}H_{z}, OH, or OₓC_{y}H_{z},
contacting the substrate with a reactant comprising at least one of N₂, NₓH_{y}C_{z}, HₓH_{y}, N_{z}H_{y}/Oxidizer, NₓH_{y}/H₂, PₓC_{y}H_{z}, BₓC_{y}H_{z}, O₂, O₃, N₂O, CO₂, H₂O, or H₂/O₂; and
applying RF power to the reaction space.

6. A method of depositing a silicon oxide film on a surface of a substrate within a reaction space by plasma-enhanced atomic layer deposition (PEALD), the method comprising:
contacting the substrate with a chemical precursor comprising at least one of: 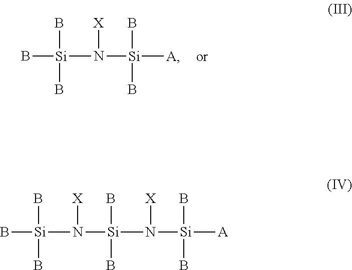
wherein A is selected from a group comprising NH₂, NₓC_{y}H_{z}, or H;
wherein B is selected from a group comprising H, C_{y}H_{z}, NH₂, NₓC_{y}H_{z}, OH, or OₓC_{y}H_{z}; and wherein X does not comprise C, H, or Si;
contacting the substrate with a reactant comprising at least one of O2, O3, N2O, CO2, H20, H2/O2, or NzHy/Oxidizer; and
applying RF power to the reaction space.
